(19) United States
(12) Patent Application Publication
(10) Pub. No.: US 2025/0054746 A1
(43) Pub. Date: Feb. 13, 2025

(54) METHOD FOR PRODUCING SEMICONDUCTOR COMPONENTS FROM A WAFER WITH SELECTIVE APPLICATION OF EDGE INSULATION

(71) Applicant: Robert Bosch GmbH, Stuttgart (DE)

(72) Inventors: Bernhard Polzinger, Stuttgart (DE); Christian Foerster, Reutlingen (DE); Jens Buettner, Reutlingen (DE); Karl Schuell, Reutlingen (DE); Kristina Vogt, Muenchingen (DE)

(21) Appl. No.: 18/794,441

(22) Filed: Aug. 5, 2024

(30) Foreign Application Priority Data
Aug. 11, 2023 (DE) 10 2023 207 741.8

(51) Int. Cl. H01L 21/02; H01L 21/304; H01L 21/8258

(52) U.S. Cl. CPC H01L 21/02118; H01L 21/02288; H01L 21/02348; H01L 21/304; H01L 21/8258

(57) ABSTRACT

A method for producing a plurality of semiconductor components, in particular power semiconductor components, from a wafer. The method includes: providing a wafer substrate, processing a structured wafer surface, applying edge insulation to the wafer surface, and separating the wafer into individual semiconductor components.

### CROSS REFERENCE

The present application claims the benefit under 35 U.S.C. § 119 of German Patent Application No. DE 10 2023 207 741.8 filed on Aug. 11, 2023, which is expressly incorporated herein by reference in its entirety.

### FIELD

The present invention relates to a method for producing semiconductor components from a wafer, wherein selective application of edge insulation of the semiconductor components or the power electronics is carried out by means of an additive manufacturing process.

### BACKGROUND INFORMATION

Generally, power semiconductors can be produced on a large scale by means of so-called wafer substrates, using conventional manufacturing methods from clean room or microsystem technology. To manufacture a power semiconductor or semiconductor chip, a wafer made of silicon (Si) or silicon carbide (SiC) having a diameter of, for example, 150 mm, 200 mm, or 300 mm is generally processed over a plurality of individual steps.

The power semiconductors or chips processed on the wafer require an insulator or so-called edge insulator at the edge, in the region of a sawing edge provided for separation, to protect against electrical flashovers. This insulator also serves as a seal against grinding water when back-thinning the wafer. Furthermore, the insulator passivates the edge region of the chip and protects its edge region from contamination or moisture over the lifetime of the chip. The material for the edge insulator is usually applied by spin coating and developed using a UV light exposure process. This lithographic coating and structuring process takes place in semiconductor manufacturing in the so-called BEOL (back end of line).

A disadvantage of the conventional method is that a plurality of process steps are necessary and only a part of the applied material is ultimately needed, which makes the process cost- and resource-intensive. In addition, the edge insulator is applied to the entire wafer and thus also to semiconductor chips that turn out to be non-functional in later wafer testing in the back-end process and which, due to the complex manufacturing process, make up a significant portion of the chips on the wafer. Furthermore, depending on the product, a different layer thickness is required for the insulator, for example 5 μm and 12 μm, for each of which separate systems comprising a spin coater, an exposure unit, and a cleaner for different layer thicknesses must be provided in production. Also, due to inaccuracy in the alignment at the wafer edge, this process cannot be carried out all the way to the edge, which results in wafer area being lost, so that fewer chips can be produced per wafer.

### SUMMARY

The present invention relates to a method for producing a plurality of semiconductor components, in particular power semiconductor components, from a wafer. According to an example embodiment of the present invention, the method comprises the steps of:
providing a wafer substrate,
processing a structured wafer surface,
applying edge insulation to the wafer surface, and
separating the wafer into individual semiconductor components, wherein, according to the present invention, the edge insulation is applied to the wafer surface as a printed electrical insulator by means of digital printing technology.

Advantageous further developments of the method according to the present invention for producing a plurality of semiconductor components from a wafer are disclosed herein.

The inventive design of the edge insulation as a printed electrical insulator results in not only a significant saving of materials and resources, in particular a minimization of chemical waste, but also the advantage of simplified process control compared to the method known from the prior art. As a result, the production of different layer shapes and/or thicknesses on one system is possible, and can be selected individually for each incoming wafer. The changing chip sizes and layouts can be introduced and adapted quickly and easily using the printing technology. In addition, there is no need for time-consuming and costly mask changes or phasing in of new masks. Furthermore, the edge insulation can be processed or applied to the entire wafer surface with consistent precision.

Preferably, the edge insulation is selectively applied in predefined regions of the wafer surface, in particular in regions of a sawing edge of the wafer provided for separating the individual semiconductor components or semiconductor chips. The edge insulation here is preferably applied to the wafer surface according to a predefined layout. Compared to the prior art, this enables selective and precise application of the edge insulation while reducing material consumption.

According to an example embodiment of the present invention, the application of the edge insulation preferably comprises the application of an organic or inorganic ink, which is subsequently cured. The ink preferably consists of a light-sensitive material composition, in particular a polymer mixture, which can be cured by irradiation with UV light or a suitable energy and/or heat source.

The application of the ink can be carried out in a conventional manner using a corresponding print head which is arranged such that it can move relative to the wafer surface or a work surface supporting the wafer. The ink can be applied layer by layer from a nozzle or nozzles of the print head provided for this purpose, wherein each of the applied layers can be cured immediately or periodically.

In a preferred embodiment of the present invention, the application of the edge insulation comprises the application of at least one layer having a layer thickness of between 5 and 30 μm. To achieve or apply edge insulation having a greater layer thickness, repeated application of material may be necessary. In this case, the application of the edge insulation can in particular comprise the application of a plurality of layers, which are applied on the wafer surface one over the other, preferably with subsequent curing in each case.

Advantageously, according to an example embodiment of the present invention, after the application of the edge insulation, the method may comprise a leveling step in which a predefined and preferably uniform layer thickness of the edge insulation is created or achieved on the wafer surface. This can, for example, be done using a doctor blade. In particular, excess ink can also be removed or the surface of the applied layer or layers can be smoothed.

After the edge insulation has been applied, in an optional additional step, final curing under UV light or an appropriate heat treatment can take place. This ensures complete hardening and strengthening of the edge insulation material.

According to an example embodiment of the present invention, the step of applying the edge insulation to the wafer surface is preferably carried out before a wafer back-thinning process in which the wafer is reduced from its original wafer thickness to a component thickness desired or necessary for the later application of the semiconductor components or chips. Depending on the specific requirements of the production process and the desired thickness of the wafer, this can be done for example by grinding, chemical-mechanical polishing (CMP), or etching.

According to an example embodiment of the present invention, the step of applying the edge insulation can alternatively be carried out together with the application of a so-called carrier wafer, and in particular together with the application of a printed carrier wafer. This serves to support and protect the wafer during handling and further process steps. The printed carrier wafer can also be applied using digital printing technology.

Preferably, according to an example embodiment of the present invention, the edge insulation is first applied in a first process step and then the printed carrier wafer is applied. Advantageously, a support layer or a support material can be applied in the regions in which no edge insulation is applied or printed. This can be applied in a layer thickness equal to the layer thickness of the edge insulation and/or be designed in such a way that its surface lies in the same plane as the surface of the edge insulation. The support layer can here also be applied using digital printing technology.

According to an example embodiment of the present invention, the step of applying the edge insulation can alternatively be carried out following a back-thinning process and an electrical wafer test, in which the functionality and quality of the wafer is checked before it is further processed and cut or separated into individual semiconductor components or chips. Wafer testing typically occurs after the BEOL process, in which the circuits and connections are produced on the wafer, and consists of a series of electrical and functional tests to ensure that the wafer functions properly and meets the relevant specifications. The edge insulation is preferably applied only, i.e. exclusively, for the semiconductor components tested as functional in the wafer test or corresponding to the predetermined specifications. This allows the use of materials to be significantly further reduced.

Furthermore, the present invention relates to a semiconductor component, in particular a power semiconductor component, which is or can be produced according to the method of the present invention described above, wherein the semiconductor component has edge insulation which is formed by a printed electrical insulator. In particular, the edge insulation is applied using digital printing technology or an additive manufacturing process.

In order to avoid repetition, reference is made here to the above-mentioned statements on the method according to the present invention, which are equally to be considered as disclosed for the device according to the present invention.

Further advantages and details of the present invention can be found in the following description of preferred embodiments of the present invention and with reference to the figures, which are merely schematic.

### BRIEF DESCRIPTION OF THE DRAWINGS

FIG. 1A shows a plan view of a structured top side of a wafer having a plurality of wafer cells for later separation into semiconductor devices, according to an example embodiment of the present invention.

FIG. 1B shows a detailed view of FIG. 1A having a plurality of wafer cells arranged next to each other, according to an example embodiment of the present invention.

FIG. 1C is a detailed view of FIG. 1B having applied edge insulation of a wafer cell or a semiconductor component according to the present invention of the wafer before separation, according to an example embodiment of the present invention.

FIG. 2A-C are cross-sectional views of a wafer cell or a functional block of a wafer to illustrate individual method steps of a preferred embodiment of the method according to the present invention.

### DETAILED DESCRIPTION OF EXAMPLE EMBODIMENTS

Identical elements or elements which have the same function are provided with the same reference signs in the drawings.

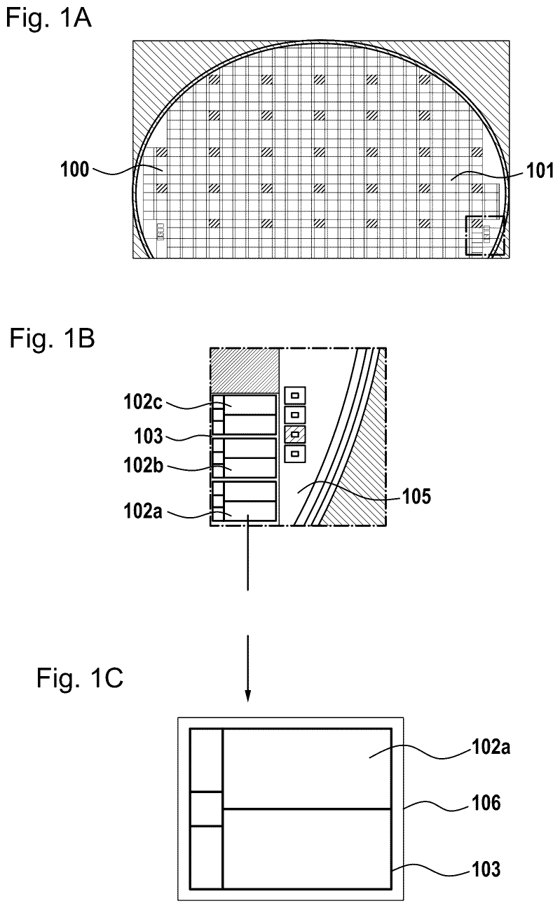

In FIG. 1A, a wafer 100 is shown in a perspective plan view, wherein a plurality of wafer cells or functional blocks 102a, b, c are arranged or structured on the illustrated top side 101, which form the later semiconductor components or chips.

As shown in FIGS. 1B and 1C, edge insulation 103 is applied or printed on the wafer top side 101, which separates the individual chips 102a, 102b, 102c from each other and protects them from external influences. In particular, undesirable electrical interactions or short circuits between the chips 102a, 102b, 102c can be prevented.

Using the method according to the present invention, the edge insulation 103 is applied or arranged selectively in predefined regions of the wafer top side 101, in particular comprising regions of the saw edge(s) 106 of the wafer 100 provided for separating the individual chips. The edge insulation 103 is formed by an electrical insulator printed using digital printing technology.

The edge insulation 103 can be applied to the wafer surface 101 before a wafer back-thinning process. Alternatively, the edge insulation 103 can be applied after a back-thinning process, and in particular after an electrical wafer test. In this case, the edge insulation 103 is preferably applied selectively only for the wafer cells or chips 102a, 102b, 102c which were tested in the wafer test as being functional or as fulfilling predetermined specifications.

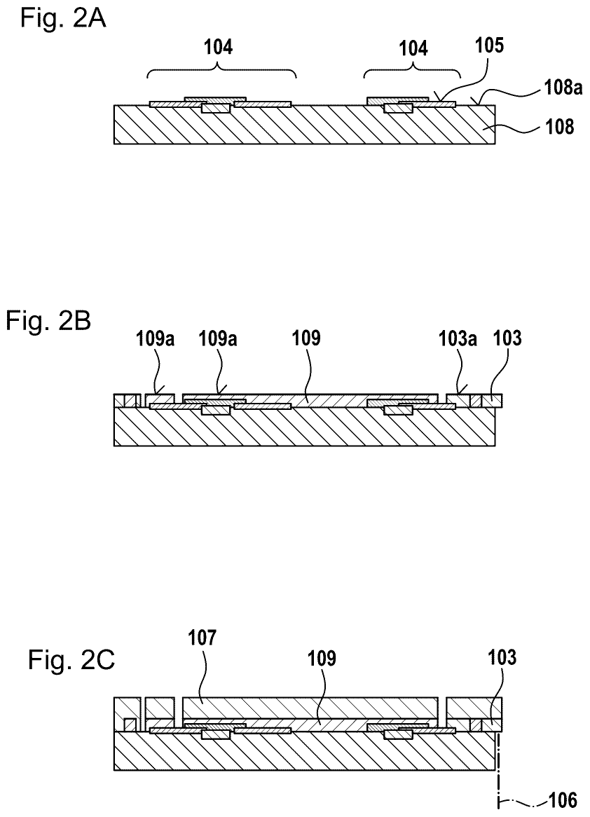

FIG. 2A-2C show method steps of a further preferred embodiment of the method according to the present invention, in which the application of the edge insulation 103 takes place together with a carrier wafer 107 and in particular a printed carrier wafer.

As shown in FIG. 2A, a wafer substrate 108, for example consisting of silicon (Si), silicon carbide (SiC) or gallium nitride (GaN), is first provided as a basis for processing the semiconductor components to be formed on the wafer. In a manner known per se, the desired layers and structures 104, or those specified in the process, for producing semiconductor components such as transistors, diodes or integrated circuits are then formed on a wafer substrate surface 108a.

As shown in FIG. 2B, in the next step edge insulation 103 is applied onto the surface 105 of the processed or structured wafer 100. The edge insulation 103 is here preferably applied as an organic or inorganic ink with a corresponding print head, and only in predefined regions of the surface. In particular, the edge insulation 103 is applied in the region of sawing edges 106 of the wafer 100 that are provided for separating the individual semiconductor components or semiconductor chips. The edge insulation 103 is applied to the wafer surface in particular in layers, preferably with a layer thickness between 5 and 30 μm, and then cured by irradiation with UV light or a suitable energy and/or heat source. To achieve greater layer thicknesses, a plurality of layers can be applied on top of each other and then cured.

To achieve a uniform surface for the subsequent application of a printed carrier wafer 107, a support layer 109 is preferably applied to the wafer surface 10 in addition to the edge insulation 103. This is applied in particular to the regions of the wafer to which the carrier wafer 107 is to be applied and in which edge insulation 103 has not already been applied. The support layer is preferably applied to the wafer surface 105 and the formed semiconductor structures 104 in such a way that their surface 109a lies in a plane with the surface 103a of the edge insulation 103. The support layer 107 is preferably also applied using digital printing technology.

As shown in FIG. 2C, in a further step a printed carrier wafer 107 is applied to the regions of the surfaces of the edge insulation 103 and the support layer 107 provided for this purpose. The carrier wafer 107 is also applied in a manner known per se using digital printing technology.

In a subsequent manufacturing step (not shown), the wafer 100 is separated or singulated by separating the semiconductor components 102a, 102b, 102c at the provided saw edges 106.

What is claimed is:

1. A method for producing a plurality of semiconductor components including power semiconductor components, from a wafer, the method comprising the following steps:
providing a wafer substrate;
processing a structured wafer surface;
applying edge insulation to the wafer surface; and
separating the wafer into individual semiconductor components;
wherein the edge insulation is applied to the wafer surface as a printed electrical insulator using digital printing technology.

2. The method according to claim 1, wherein the edge insulation is selectively applied in predefined regions of a sawing edge of the wafer provided for separation.

3. The method according to claim 1, wherein the application of the edge insulation includes application of an organic or inorganic ink and subsequent curing.

4. The method according to claim 1, wherein the application of the edge insulation includes application of at least one layer having a layer thickness of between 5 to 30 μm.

5. The method according to claim 1, wherein the application of the edge insulation includes application of a plurality of layers which are applied to the wafer surface one over the other.

6. The method according to claim 1, wherein the application of the edge insulation includes application of a plurality of layers which are applied to the wafer surface one over the other with subsequent curing in each case.

7. The method according to claim 1, further comprising a leveling step in which a uniform layer thickness of the edge insulation is created on the wafer surface.

8. The method according to claim 1, wherein the application of edge insulation on the wafer surface takes place before a back-thinning process of the wafer.

9. The method according to claim 1, wherein the application of the edge insulation on the wafer surface takes place after a back-thinning process and an electrical wafer test.

10. The Method according to claim 1, wherein the application of the edge insulation on the wafer surface takes place together with an application of a printed carrier wafer.

11. A semiconductor component, the semiconductor component having has edge insulation which is formed by a printed electrical insulator.

12. The semiconductor component according to claim 11, wherein the semiconductor component is manufactured by:
providing a wafer substrate of a wafer;
processing a structured wafer surface;
applying the edge insulation to the wafer surface as a the printed electrical insulator using digital printing technology; and
separating the wafer into individual semiconductor components.
